(19) United States
(12) Patent Application Publication
(10) Pub. No.: US 2025/0138604 A1
(43) Pub. Date: May 1, 2025

(54) HOT SWAPPABLE DRIVE CAGE

(71) Applicant: HEWLETT PACKARD ENTERPRISE DEVELOPMENT LP, Spring, TX (US)

(72) Inventors: Vance Brey Murakami, Los Gatos, CA (US); Paul Wesley Stelter, San Bruno, CA (US)

(21) Appl. No.: 18/495,962

(22) Filed: Oct. 27, 2023

(51) Int. Cl. G06F 1/18; H05K 7/14

(52) U.S. Cl. CPC G06F 1/187; H05K 7/1401; H05K 7/1489

(57) ABSTRACT

A hot-swappable drive cage is removably installable in an information processing device. The drive cage has multiple bays to carry multiple media drives. The drive cage and the media drives carried thereon can be removably inserted, together as a unit, into a drive cage receptacle of the information processing device, and when the drive cage reaches an installed position in the receptacle, the media drives are all electrically connecting to the information processing device. The drive cage and the media drives carried thereon can also be removed, together as a unit, from the drive cage receptacle, resulting in the media drives all being disconnected from the information processing device. The drive cage may comprise injector/ejectors to convert actuation forces supplied thereto into insertion forces and ejection forces that force the drive cage to translate relative to the chassis into or out of the installed position, depending on the actuation direction.

Information processing devices, such as computers, generally comprise a variety of components, including, among others, media drives, such as hard disk drives (HDD) or solid-state drives (SSD). In some computers, the media drives are configured as pluggable modules, which are designed to be installable and removable from the computer without requiring disassembly of the computer. In some cases, the drives are removable/installable while the computer is still powered on, which is also referred to as being hot-swappable. For example, the computer may comprise a chassis, and the chassis may include a drive cage which has a number of bays which are accessible from an exterior of the chassis and are each configured to removably receive a media drive. A backplane may be provided at the rear of the drive cage, with blind-mate electrical connectors being disposed on the backplane in alignment with the bays such that, as drives are inserted into the bays, electrical connectors of the drives automatically engage with the backplane connectors. The backplane is also electrically connected to other components of the system, such as a CPU, and thus the installed drives are electrically connected to these other components via the backplane.

### BRIEF DESCRIPTION OF THE DRAWINGS

The present disclosure can be understood from the following detailed description, either alone or together with the accompanying drawings. The drawings are included to provide a further understanding of the present disclosure and are incorporated in and constitute a part of this specification. The drawings illustrate one or more examples of the present teachings and together with the description explain certain principles and operations. In the drawings:

FIG. 1 is a block diagram schematically illustrating an information processing system comprising an information processing device and a hot-swappable drive cage.

FIG. 2 is a perspective view of another example information processing system comprising an information processing device and a hot-swappable drive cage in a state of the hot-swappable drive cage installed in the information processing device.

FIG. 3 is a front view of the information processing system of FIG. 2 in the state of the hot-swappable drive cage installed in the information processing device.

FIG. 4 is a perspective view of the information processing system of FIG. 2 in a state of the hot-swappable drive cage uninstalled from the information processing device.

FIG. 5 is a front-perspective view of the hot swappable drive cage of the information processing system of FIG. 2 in an uninstalled state.

FIG. 6 is a rear-perspective view of the hot swappable drive cage of the information processing system of FIG. 2 in the uninstalled state.

FIG. 7 is a partial perspective view of the information processing device of the information processing system of FIG. 2 showing a drive cage receptacle of the information processing device with the hot-swappable drive cage uninstalled.

FIG. 8 is a partial perspective view of the information processing system of FIG. 2 showing a cage injector/ejector mechanism in the installed state of the hot-swappable drive cage.

FIG. 9 is a partial front view of the information processing system of FIG. 2 showing the cage injector/ejector mechanism in the installed state of the hot-swappable drive cage.

FIG. 10 is a partial perspective view of the hot-swappable drive cage of the system of FIG. 2 showing a cage injector/ejector mechanism in the uninstalled state of the hot-swappable drive cage.

FIG. 11 is a partial plan view of the hot-swappable drive cage of the system of FIG. 2 showing the cage injector/ejector mechanism in the uninstalled state of the hot-swappable drive cage.

FIG. 12 is a partial perspective view of the hot-swappable drive cage of the system of FIG. 2 showing a second example cage injector/ejector mechanism in the uninstalled state of the hot-swappable drive cage.

FIG. 13 is a partial plan view of the hot-swappable drive cage of the system of FIG. 2 showing the second example cage injector/ejector mechanism in the uninstalled state of the hot-swappable drive cage.

FIG. 14 is a partial perspective view of the information processing system of FIG. 2 showing a lockdown mechanism on a top side of the hot-swappable drive cage in the installed state of the hot-swappable drive cage.

FIG. 15 is a partial plan view of the information processing system of FIG. 2 showing the lockdown mechanism in the installed state of the hot-swappable drive cage.

FIG. 16 is a cross-section the information processing system of FIG. 2 showing the lockdown mechanism in the installed state of the hot-swappable drive cage, with the section taken along the plane indicated by the line 16-16 in FIG. 15.

FIG. 17 is a cross-section the information processing system of FIG. 2 showing another lockdown mechanism on a bottom side of the hot-swappable drive cage in the installed state of the hot-swappable drive cage, with the section taken along the plane indicated by the line 17-17 in FIG. 3.

### DETAILED DESCRIPTION

In many scenarios in which information processing devices are commonly used, such as in day-to-day operation of a datacenter or a business's information technology facilities, the removal and/or installation of removable media drives is a common occurrence and is relatively easily performed. Removal of an individual drive usually comprises pulling an ejection lever that is part of the drive, which forces the drive to move partially out of the bay and disconnect from the backplane's electrical connectors, whereupon the technician can freely pull the drive the rest of the way out of the bay. For installation, the drive is aligned with and inserted into the bay until the electrical connectors begin to engage, whereupon the lever on the drive can be pushed in to force the drive into the fully installed position with fully engaged connectors. Generally, the environment in which the installation/removal occurs (e.g., in a datacenter) is clean, stable, and low stress, and the installation/removal are usually pre-planned and scheduled for convenient times. These good conditions enable the technicians to take the care necessary to avoid damage to the components being handled and to complete the installation and removal with relative ease.

However, in some applications, a computer with multiple pluggable media drives (e.g., a server) may need to have its media drives replaced under much more adverse conditions. Such adverse conditions may occur, for example, in certain military, industrial, or aerospace applications. These adverse conditions may include adverse environmental conditions, such as a physically unstable environment (e.g., in a moving vehicle), a potentially unsafe environment (e.g., in a warzone, in a mine, etc.), and/or in an otherwise stressful environment. The adverse conditions may also include adverse time constraints, such as when the need for installation/removal manifests at an unscheduled timing and/or when the installation/removal need to be completed rapidly.

For example, a computer may be used in a vehicle (e.g., a military vehicle, an industrial vehicle, an aerospace vehicle, etc.) while the vehicle is deployed in the field on a mission, with the computer recording information about the mission (e.g., video recordings, sensor readings, etc.). In such a scenario, if the media drives become full while the mission is still in progress, the mission personnel may need to replace the full media drives with fresh drives to allow for the mission to continue. However, the vehicle may be moving, which can make installation/removal more challenging. Moreover, in some cases, stress, time constraints and other adverse conditions can increase the likelihood of human error while handling the components, such as dropping individual drives or forcing misaligned drives into the bays, which may potentially damage their connectors. Another error that may be more likely to occur under stressful and time-constrained scenarios is the installation of new drives in incorrect bay positions, which can be a problem when technologies are being used that need a particular positional arrangement of drives (such as an Redundant Array of Independent Disks (RAID)).

Furthermore, even if the removal/installation proceeds without any human error, nevertheless it may take a relatively long time for the process to be completed, due to each drive having to be removed and installed one at a time. While removal and installation of a single drive may be relatively quick, when many drives are present the total time needed for the entire replacement process can add up (e.g., it is not uncommon for there to be two dozen or more drives). Moreover, the time required for the replacement process includes not only the time for each individual drive removal event or drive insertion event, but also the time in between such events in which the individual removed drives have to be stowed, one at a time, in a safe location with due care to avoid damage and in which individual new drives have to be retrieved, one at a time, from whatever container they are stored in. Thus, the long time spent replacing the drives can delay the mission progress or otherwise be undesirable.

A technical solution to the above-described problems comprises an information processing system in which a drive cage holding multiple media drives is removable from, and installable in, an information processing device (e.g., computer) all at once as a single unit. In particular, the drive cage may be insertable and removable in a hot-swappable manner, and thus the drive cage may be referred to herein as a hot-swappable drive cage. As the drive cage is inserted into a drive cage receptacle of the information processing device, all of the media drives carried in the drive cage may concurrently engage with electrical connectors of a backplane of the information processing device. Conversely, as the drive cage is removed from the drive cage receptacle, all of the media drives carried by the drive cage may concurrently disengage from the electrical connectors of the backplane.

In examples disclosed herein, the hot-swappable drive cage may comprise a series of progressive alignment features which are configured to sequentially engage with portions of the information processing device as the drive cage is inserted into the drive cage receptacle and thereby progressively align the drive cage to a desired installed position. A first stage of alignment features may provide gross positioning of the drive cage within the drive cage receptacle and may incorporate generous leeway (play or tolerance) at the leading engagement surfaces thereof so that a user does not have to struggle to perfectly align the drive cage before beginning the insertion. Then, as the drive cage continues to be inserted farther into the drive cage receptacle, subsequent stages of alignment features engage with portions of the information processing device, with each stage of alignment features providing progressively tighter constraints to eventually bring the drive cage into the installation position. In this way, the drive cage can be aligned with sufficient precision to allow for mating with the connectors of the backplane while also remaining relatively easy for a user to install.

In examples disclosed herein, the hot-swappable drive cage may comprise one or more injection/ejection mechanisms to aid the user in insertion of the drive cage into or removal of the drive cage from the drive cage receptacle. Each injection/ejection mechanism comprises a lever which is actuatable by the user, together with a gear assembly coupled to the lever such that actuation of the lever is converted into rotation of the gears of the gear assembly. The gears are configured to engage with a rack (i.e., linear gear) which is coupled to the chassis of the information processing device forming a type of rack-and-pinion, such that actuation of the lever causes translation of the drive cage relative to the chassis. The injection/ejection mechanism is configured to create a mechanical advantage to help the user overcome the frictional resistance to engagement or disengagement of the drives to/from the electrical connectors of the backplane. Because multiple drives are engaged with the backplane connectors simultaneously when the drive cage is installed, the total insertion force required may be very large—in some cases, too large for a user to comfortably apply unaided. For example, around 300 lbs. of insertion force may be needed in some devices with twenty-four drives. Similarly, large ejection forces are also needed to disengage all the drives from the backplane simultaneously. However, in examples disclosed herein, the mechanical advantage provided by the injection/ejection mechanism allows a sufficiently high insertion force to be applied between the chassis and drive cage with the user only supplying a moderate force to the lever (e.g., around 12 lbs., in some examples).

In some examples, the gear assembly of the injection/ejection mechanism may comprise multiple pinion gears which are configured to be concurrently actuated by the same lever. Providing multiple pinion gears further increases the mechanical advantage of the mechanism (as compared to if a single pinion gear were present). In some examples in which the injection/ejection mechanism comprises multiple pinion gears, the rack may comprise multiple tiers which are arranged in a line (in a forward-rearward direction). A first tier of the rack may be closest to the front of the chassis and may protrude into the receptacle a first distance, and a second tier of the rack may be positioned rearward of the first tier and may protrude a second distance, which is greater than the first distance. In such examples, the pinion gears may include a first gear closer to a front of the drive cage and second gear farther rearward, with the two gears being slightly offset, such that the first pinion gear can engage with the first tier of the rack and the second pinion gear can engage with the second tier of the rack. The tiering of the rack allows the second pinion gear to move past the first tier during insertion of the drive cage without the second pinion gear getting hung up on the first tier of the rack.

In some examples, multiple injection/ejection mechanisms are provided on the drive cage. This may ensure that the very large insertion force that may be needed is spread out over multiple contact points with the chassis of the information processing device. This can help reduce the risk of the drive cage skewing during insertion, which could cause misalignment and/or binding. For example, in some implementations four injection/ejection mechanisms are provided, with each being near one of the four corners of the front portion of the drive cage. In some examples, the levers of the two injection/ejection mechanisms on a left side of the drive cage may be coupled together via a first handle and the two injection/ejection mechanisms on a right side of the drive cage may be coupled together via a second handle, such that a user can actuate all four ejection mechanisms simultaneously by grasping the two handles (e.g., one in each hand) and pushing them simultaneously toward the drive cage (for injection) or pulling them simultaneously away from the drive cage (for ejection). In some examples, the handles may also serve as carrying handles which allow for the user to carry the drive cage when removed from the information processing device.

The examples disclosed herein may provide a number of benefits and advantages, particularly relative to other approaches described above. For example, in a scenario in which all of the drives in the system need to be replaced, the hot-swappable drive cage allows for all of the drives to be removed and replaced very rapidly. For example, the user may remove all the existing drives all at once by simply removing the hot-swappable drive cage, stow all the drive cages at once by stowing the drive cage, and then the user may install a full set of new drives all at once by installing a new hot-swappable drive cage which was previously loaded with new drives (e.g., the new drives may have been preloaded prior to the start of the mission in anticipation of the possible need to change drives during the mission). This simple process may be much faster than replacing the same number of drives by individually removing the drives one-at-a-time, stowing them individually one at a time, and then individually inserting the new drives one-at-a-time.

The ability to replace all of the drives with just one removal action and one insertion action not only reduces the amount of time the overall process takes, but it also reduces the likelihood of human error occurring during the process. More specifically, each insertion and removal event may have a chance of human error, which is amplified in an adverse environment. Thus, the more insertions or removals that occur, the more likely it is that a human error will occur. Accordingly, conventional systems which require multiple drive insertion and removal events (e.g., up to forty-eight such events in a system with twenty-four drives) may have a higher overall chance of an error occurring than examples disclosed herein which require just two such events (e.g., one removal and one insertion in the system with twenty-four drives).

Moreover, inserting an individual drive generally requires some care to be taken so as to properly align the drive with the bay (to avoid damaging connectors), and also some fine manual manipulation of the drive may be needed (e.g., to manipulate a relatively small ejection mechanism). However, such careful precision and fine manual manipulation can sometimes be difficult when in an adverse environment (e.g., while in the field on a potentially dangerous mission), as stress or other conditions may distract the user and diminish fine motor control. In addition, mission gear (e.g., thick gloves) can also make fine manual manipulations difficult. In contrast, in examples disclosed herein, the user may be able to take less care when initially aligning the drive cage with the receptacle, due to the progressive alignment features of the drive cage. Moreover, the large handles of the injector/ejector mechanisms may be more easily actuatable by the user in a stressful environment, as this motion may involve a simple gross motor motion rather than a fine motor motion.

Furthermore, in examples disclosed herein, the chances of an incorrect drive order occurring can be greatly reduced (in those cases in which the order of the drives matters). This is because in examples disclosed herein the drives can be preloaded into the replacement drive cage at a time and place that is less stressful, less time constrained, and more conducive to careful work, such as prior to a mission starting, and an error in drive-ordering is less likely to be made in such an environment than in stressful conditions such as out in the field.

Turning now to the figures, various devices, systems, and methods in accordance with aspects of the present disclosure will be described.

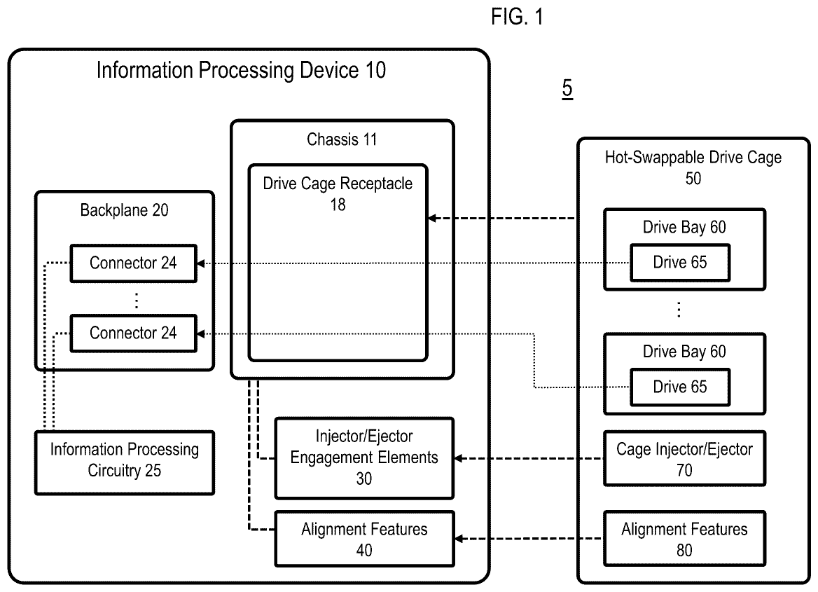

FIG. 1 is a block diagram schematically illustrating an information processing system 5. It should be understood that FIG. 1 is not intended to illustrate specific shapes, dimensions, or other structural details accurately or to scale, and that implementations of the information processing system 5 may have different numbers and arrangements of the illustrated components and may also include other parts that are not illustrated. In FIG. 1, certain physical connections or engagements are indicated by dashed lines, whereas electrical connections are indicated by dotted lines.

As shown in FIG. 1, the information processing system 5 comprises an information processing device 10 and a hot-swappable drive cage 50. The information processing device 10 may be a computer (e.g., server), networking device, or any other type of information processing device. The hot-swappable drive cage 50 is configured to carry multiple media drives 65 (e.g., HDD, SDD, etc.). Unlike conventional drive cages which are fixedly attached to and/or form an integral part of the chassis of their respective information processing devices, the hot-swappable drive cage 50 is a separate part from the information processing device 10 and to removably installable in the information processing device 10 in a hot-swappable manner. More specifically, in some examples the drive cage 50, together with the media drives 65 carried by the drive cage 50, can all be installed as a unit in the device 10, and similarly the drive cage 50, together with the media drives 65, can all be removed as a unit from the device 10.

As shown in FIG. 1, the information processing device 10 comprises a chassis 11, which comprises one or more walls, panels, and/or other structural members which support and house the components of the device 10. This chassis 11 may include a drive cage receptacle 18 in a front panel or a rear panel of the chassis 11, which is configured to removably receive the drive cage 50. The drive cage receptacle 18 is defined by walls and/or other structural members of the chassis 11. The receptacle 18 is partially enclosed, except that a front face of the receptacle 18 is open to allow for insertion of the drive cage 50 and a back face is at least partially open to a backplane 20 positioned at the rear thereof. The backplane 20 has blind-mate electrical connectors 24 mounted thereon and positioned so as to engage with complementary connectors of the media drives 65 when the drive cage 50 is inserted into the drive cage receptacle 18. The number and arrangement of blind-mate connectors 24 may correspond to the number and arrangement of drive bays 60 (discussed below) in the drive cage 50. The connectors 24 of the backplane 20 are electrically connected to information processing circuitry 25 of the device 10, such as a CPU, and thus the media drives 65 are connected with the information processing circuitry 25 via the connectors 24 when the drive cage 50 is installed.

The drive cage 50 comprises a structural frame formed from a plurality of outer walls that encloses and defines multiple internal drive bays 60. Each of the drive bays 60 is configured to removably receive, hold, and support a media drive 65. In some examples, the drive cage 50 frame may comprise top, bottom, and two side walls. An opening may be provided in a front face of the drive cage 50 to allow for media drives 65 to be inserted into and removed from the drive cage 50, in the same manner that media drives 65 can be inserted or removed into existing fixed drive cages. In addition, a rear face of the drive cage 50 is at least partially open so as to expose electrical connectors at the rear of the media drives 65. The bays 60 are configured to hold the media drives 65 in predetermined positions such that their electrical connectors will be properly aligned with, and thus can engage with, the electrical connectors 24 of the backplane 20 when the drive cage 50 is installed in the receptacle 18.

As shown in FIG. 1, in some examples the hot-swappable drive cage 50 comprise one or more alignment features 80 configured to engage with complementary alignment features 40 of the information processing device 10 to guide the drive cage 50 into the receptacle 18 and to align the drive cage 50 with a predetermined installation position. The alignment features 80 may comprise one or more of: sloped lead-in surfaces, pin receptacles, pins, chamfered edges, grooves/slots, tabs, etc. The alignment features 40 may comprise structures complementary to the alignment features 80. In some examples, the alignment features 80 comprise a series or progressive alignment features 80, which are configured to sequentially engage with various alignment features 40 as the drive cage 50 is inserted into the drive cage receptacle 18, and thereby progressively align the drive cage 50 to a desired installed position. A first stage of alignment features 80 may provide gross positioning of the drive cage 50 within the drive cage receptacle 18 and may incorporate generous leeway (play or tolerance) at the leading engagement surfaces thereof so that a user does not have to struggle to perfectly align the drive cage 50 before beginning the insertion. Then, as the drive cage 50 continues to be inserted farther into the drive cage receptacle 18, subsequent stages of alignment features 80 engage with portions of the information processing device 10, with each stage of alignment features 80 providing progressively tighter constraints to eventually bring the drive cage 50 into the installation position. In this way, the drive cage 50 can be aligned with sufficient precision to allow for mating with the connectors 24 of the backplane 20 while also remaining relatively easy for a user to install. For example, in one implementation a first stage of alignment features 80 comprises sloped lead-in surfaces and the complementary alignment features 80 comprises walls in the receptacle 18 which the sloped lead-in surface engages with and slides along; a second stage of alignment feature 80 comprises pin receptacles (e.g., with chamfered entryways) and the complementary alignment features 40 comprises pin to be received in the pin receptacles; and a third stage of alignment features 80 comprises the connectors of a drive 65 (e.g., which may have chamfered leading edges) and the complementary alignment features 40 comprises receptacles of the connectors 24 (e.g., which may also have chamfered edge) configured to receive the connectors of the drives 65.

As shown in FIG. 1, in some examples, the drive cage 50 also comprises one or more injection/ejection mechanisms 70 (also referred to as injector/ejector 70), to aid the user in insertion of the drive cage 50 into or removal of the drive cage 50 from the drive cage receptacle 18. Each injector/ejector 70 is configured to engage with a complementary injector/ejector engagement element 30 (“engagement element 30”) which is anchored to the chassis 11. The engagement element 30 may be disposed partially or fully within the receptacle 18 so that it can engage with the corresponding injector/ejector 70 as the drive cage 50 is inserted into the receptacle 18. The injector/ejector 70 is configured to be actuated by a user, and when actuated generates a force which is applied to the chassis 11 via engagement between the injector/ejector 70 and the engagement elements 30. This force is configured to drive translational motion of the drive cage 50 into or out of the receptacle. For example, when the drive cage 50 is partially installed in the receptacle 18 (e.g., the injector/ejector 70 is engaged with the engagement elements 30, but the drives 65 are not yet engaged with the connectors 24), if the user supplies first actuation forces to move the injector/ejectors 70 in a first actuation direction, the injector/ejectors 70 convert the first actuation forces into injection forces which push the drive cage 50 farther into the receptacle18 until the drive cage 50 reaches a fully installed position in which the drives 65 are fully connected to the connectors 24 (with the drives 65 all connecting substantially simultaneously with the connectors 24). In contrast, when the drive cage 50 is fully installed in the receptacle 18, if the user applies second ejection forces to move the injector/ejectors 70 in a second actuation direction, the injectors/ejectors convert the second actuation forces into ejection forces which pull the drive cage 50 out of the receptacle 18, disconnecting all of the drives 65 (substantially simultaneously) from the connectors 24. In addition, the injector/ejector 70 is configured to create a mechanical advantage to help the user overcome the frictional resistance to engagement or disengagement of the drives 65 to/from the electrical connectors 24 of the backplane 20. In some examples, the mechanical advantage provided by each injector/ejector 70 is about 12:1, in other examples about 10:1, and in other examples about 7.5:1.

In some examples, multiple injection/ejection mechanisms 70 are provided on the drive cage 50. This may ensure that the very large insertion force that may be needed is spread out over multiple contact points with the chassis 11. This can help reduce the risk of the drive cage 50 skewing during insertion, which could cause misalignment and/or binding. For example, in some implementations four injection/ejection mechanisms 70 are provided, with each being near one of the four corners of the front portion of the drive cage 50. In some examples, the levers of the two injection/ejection mechanisms 70 on a left side of the drive cage may be coupled together via a first handle and the two injection/ejection mechanisms 70 on a right side of the drive cage may be coupled together via a second handle, such that a user can actuate all four ejection mechanisms simultaneously by grasping the two handles (e.g., one in each hand) and pushing them simultaneously toward the drive cage (for injection) or pulling them simultaneously away from the drive cage (for ejection). In some examples, the handles may also serve as carrying handles which allow for the user to carry the drive cage 50 when removed from the information processing device 10.

In some examples, each injector/ejector 70 comprises a lever which is actuatable by the user to transfer the user's manually applied force to the chassis 11. In some examples, each injector/ejector 70 further comprises a mechanism to convert the rotary (pivoting) motion of the lever into translational motion of the drive cage 50, such as a cam, rack-and-pinion, or any other rotary-to-linear force conversion mechanism. Specifically, in some examples, the injector/ejector 70 comprises a gear assembly coupled to the lever such that actuation of the lever is converted into rotation of the gears of the gear assembly, and the engagement element 30 comprises a rack (linear gear) coupled to the chassis 11 and engaged with the gears such that rotation of the gears is converted into translation of the drive cage 50 relative to the chassis 11.

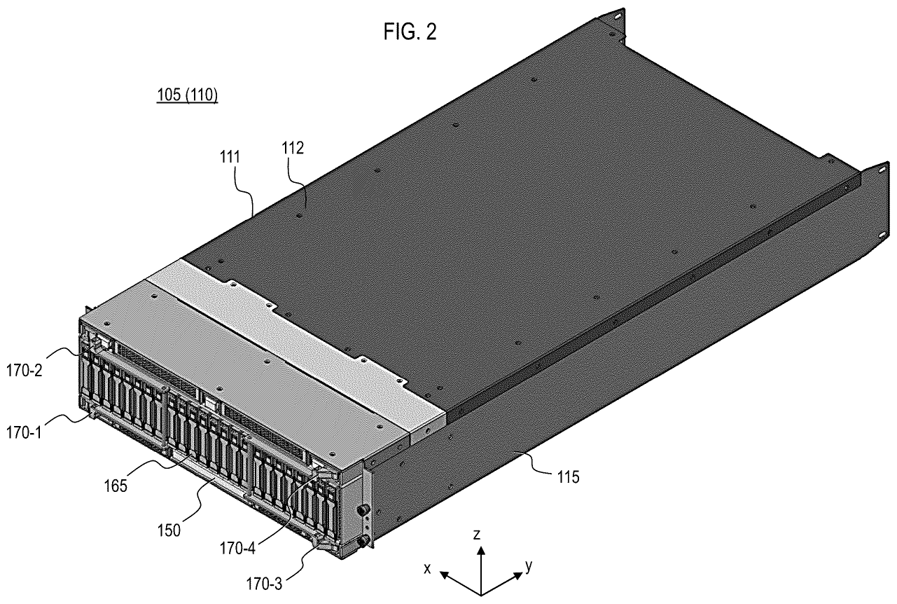

Turning now to FIGS. 2-16, another example information processing system 105 will be described, which comprises an example information processing device 110 and an example hot-swappable drive cage150. The information processing device 110 is one example configuration of the information processing device 10, and the hot-swappable drive cage 150 is one example configuration of the hot-swappable drive cage 50. Thus, some components of the information processing device 110 correspond to (i.e., are the same as, similar to, and/or example configurations of) components of the information processing device 10 described above, and some components of the hot-swappable drive cage 150 correspond to (i.e., are the same as, similar to, and/or example configurations of) components of the hot-swappable drive cage 50 described above. The components of the information processing device 110 and drive cage 50 and the components of the information processing device 10 and drive cage 50 which correspond to one another, respectively, are given reference numbers with the same last two digits, such as 70 and 170. The descriptions above of the components of the information processing device 10 and drive cage 50 are applicable to the corresponding components of the information processing device 110 and drive cage 150, respectively, (unless otherwise indicated or logically contradictory), and thus duplicative descriptions of some aspects already described above are omitted below.

FIGS. 2-16 show the information processing device 110 and/or drive cage 50 in various perspectives and in various states, and aspects thereof may be visible in multiple of the figures. The description below will refer to the figures as and when they are relevant to the aspect being described, rather than in strict numerical order. The description herein uses various directional/relational terms, such as top, bottom, left, right, front, rear, horizontal, vertical and other similar terms. These terms should be understood as referring to the objects as illustrated in the figures, but do not necessarily limit the orientations of the objects in relation to some external reference frame (such as the ground). For example, the side of an object that is the “top” side as illustrated in the figure and as described herein may appear as if it were the bottom of the object from the perspective of a ground-based external reference frame if the object is rotated 180 degrees relative to the ground. In other words, in practice the objects and be moved about in space, rotated, and oriented in any desired manner, and the directional terms used herein to not limit this. Up or similar terms refer generally to a +z direction illustrated in the figures, and top refers to a portion of an object that is positioned farther along the +z direction than other portions thereof. Down or similar terms refer generally to a −z direction illustrated in the figures, and bottom refers to a portion of an object that is positioned farther along the −z direction than other portions thereof. Left or similar terms refer generally to a +x direction illustrated in the figures, and a left side refers to a side of an object that is positioned farther along the +x direction than other portions thereof. Right or similar terms refer generally to a −x direction illustrated in the figures, and a right side refers to a side of an object that is positioned farther along the −x direction than other portions thereof. Rearward or similar terms refer generally to a +y direction illustrated in the figures, and rear refers to portion of an object that is positioned farther along the +y direction than other portions thereof. Forward or similar terms refer generally to a −y direction illustrated in the figures, and front refers to portion of an object that is positioned farther along the −y direction than other portions thereof.

In some cases, in which multiple instances of the same component are present, only one or a few of the instances of that component are labeled in the figures to avoid obscuring other features—for example, there are multiple drives 165 illustrated in FIGS. 2-16, and just one is labeled in each figure. One of ordinary skill in the art would understand in those cases in which multiple instances are shown and/or described but only one is labeled which elements in the figures correspond to other (unlabeled) instances of the component in question based on their appearance in the figures, based on the context provided in the written description, and based on the baseline knowledge of those of ordinary skill in the art.

As shown in FIG. 2, the information processing system 105 comprises an information processing device 110 and a hot-swappable drive cage 150. The information processing device 110 may be a computer (e.g., server), networking device, or any other type of information processing device. As shown in FIGS. 2-6, the hot-swappable drive cage 150 is configured to carry multiple media drives 165 (e.g., HDD, SDD, etc.). The media drives 165 may comprise an electronic module portion 167 and a drive carrier portion 166, with the drive carrier portion 166 providing a frame to support the electronic module portion 167, as well as engagement feature to engage with the bays 160, latching features (not labeled) including an ejection lever (not labeled), as would be familiar to those in the art. The media drives 165 may comprise, in some examples, commercially available and/or industry standard form factor media drives.

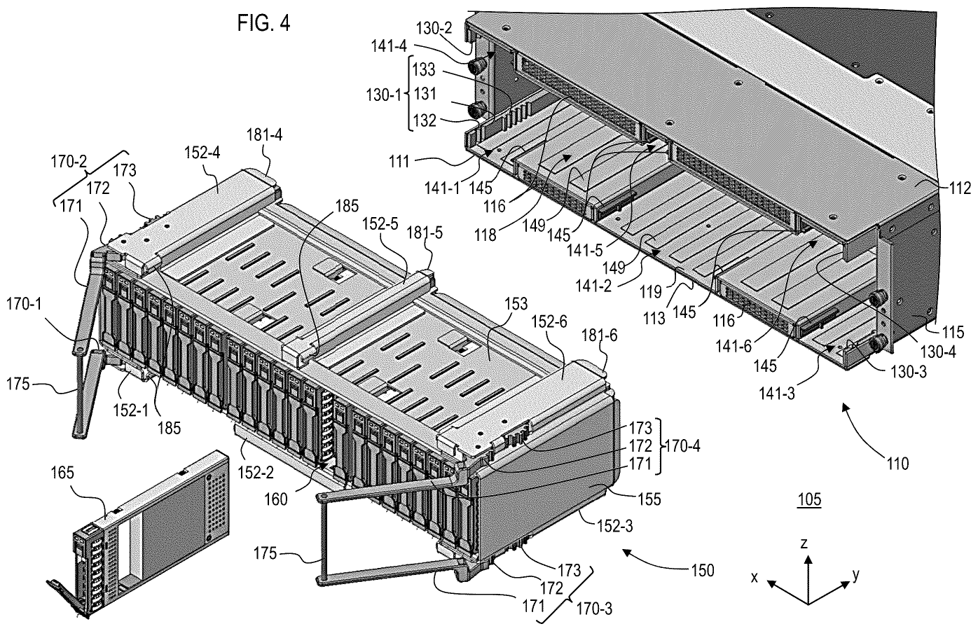

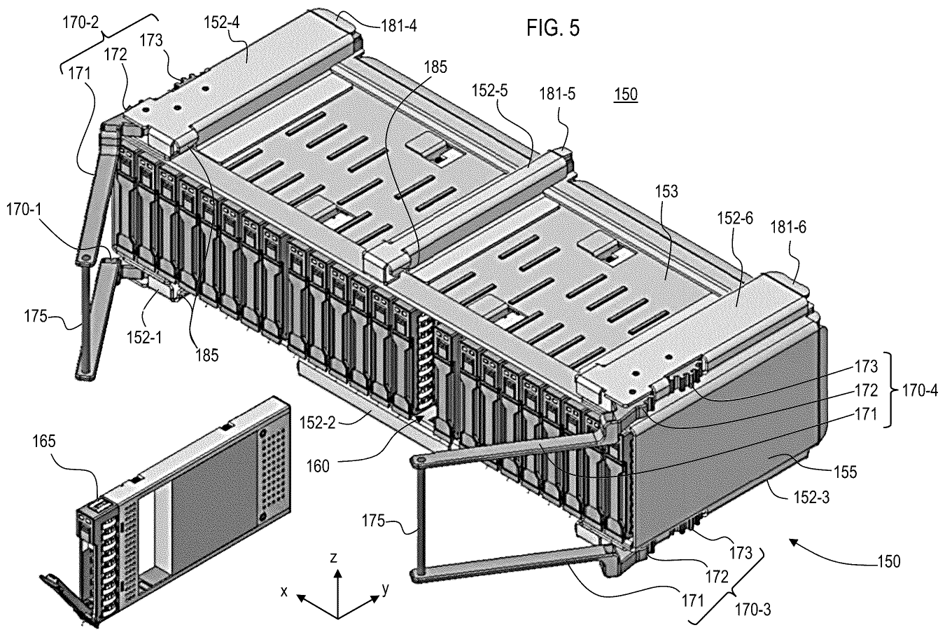

As shown in FIGS. 4 and 5, unlike conventional drive cages which are fixedly attached to and/or form an integral part of the chassis of their respective information processing devices, the hot-swappable drive cage 150 is a separate part from the information processing device 110 and is removably installable in the information processing device 110 in a hot-swappable manner. More specifically, in some examples the drive cage 150, together with the media drives 165 carried by the drive cage 150, can all be installed as a unit in the device 110, and similarly the drive cage 150, together with the media drives 165, can all be removed as a unit from the device 110. The drive cage 150 comprises injection/ejection mechanisms 170 (also referred to as “ejector/ejector 170”), which provide mechanical advantage to aid in installation and removal of the drive cage.

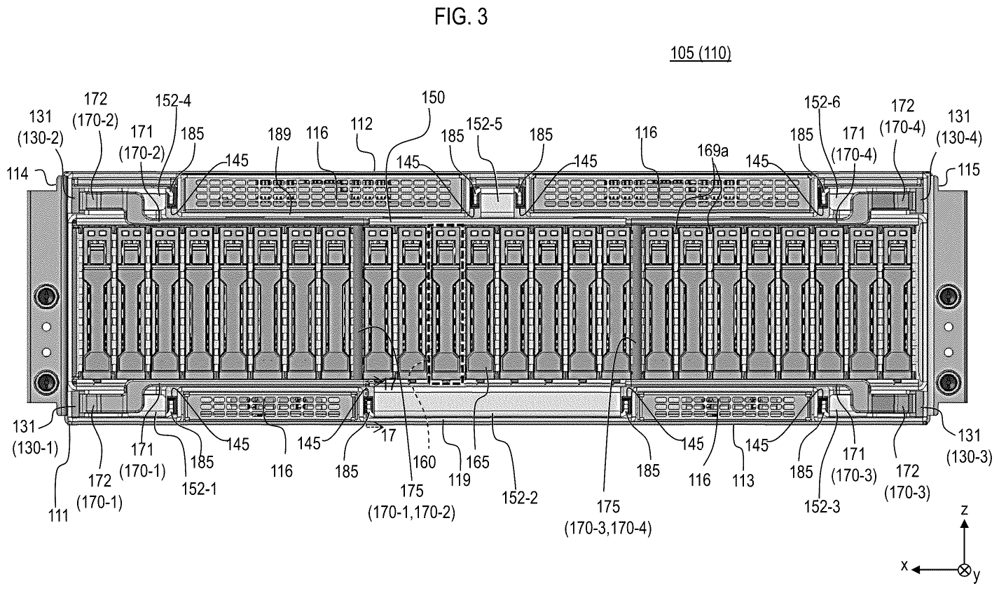

For example, from a state of the drive cage 150 uninstalled from the information processing device 110 (see FIG. 4), a state of the drive cage 150 installed in the information processing device 110 (see FIGS. 2 and 3) can be achieved by aligning the drive cage 150 with a drive cage receptacle 118 of the information processing device 110 and moving the drive cage 150 along the +y direction until the drive cage 150 enters the receptacle 118, continuing to move the drive cage 150 along the +y direction until injector/ejectors 170 (described below) of the drive cage 150 engage with racks 130 (described below) of the information processing device 110, and then actuating the injector/ejectors 170 to force the drive cage 150 into the fully installed position illustrated in FIG. 2. The removal of the drive cage 150 is achieved by performing the reverse of the actions described above. The hot-swappable manner of insertion/removal refers to the drive cage 150 being insertable/removable during normal operations of the information processing device 110 without requiring any disassembly of the device 110 (such as removing a cover thereof, unscrewing screws, etc.) and without requiring a powering down of the device 110. These and other aspects of the system 105 will be described in greater detail below.

As shown in FIG. 2, the information processing device 110 comprises a chassis 111, which comprises one or more walls, panels, and/or other structural members which support and house the components of the device 110. For example, the chassis 111 may comprise a top wall 112 (see FIGS. 2 and 3), a right side wall 115 (see FIGS. 2 and 3), a left side wall 114 (see FIG. 3), and a bottom wall 113 (see FIG. 3). The chassis 111 may also comprise a front panel area, which in the illustrated example comprises a drive cage receptacle 118 and auxiliary cages 116—in other words, the front panel of the chassis 111 is not a solid panel that extends fully across the front face, but instead is mostly open so as to allow the drive cage 150 to be received into the chassis 111 via receptacle 118. When the drive cage 150 is installed in the receptacle 118, a front portion of the drive cage 150 may serve functionally as a part of the front panel of the chassis 111, although not being permanently physically attached to the chassis 111. The chassis 111 may also comprise a rear panel region (not illustrated), which may comprise electrical connectors, riser cages for expansion cards, or other components familiar to those of ordinary skill in the art. Some portions of the chassis 111 may be removable, such as a portion of the top wall 112 which may comprise a cover, but generally during operation of the device, these portions are rigidly coupled to the rest of the chassis 111 via fasteners such as screws. The chassis 111 may form the general shape of a rectangular prism (box), albeit with various openings, protrusions, recesses, and other surface features as shown and as would be familiar to those in the art.

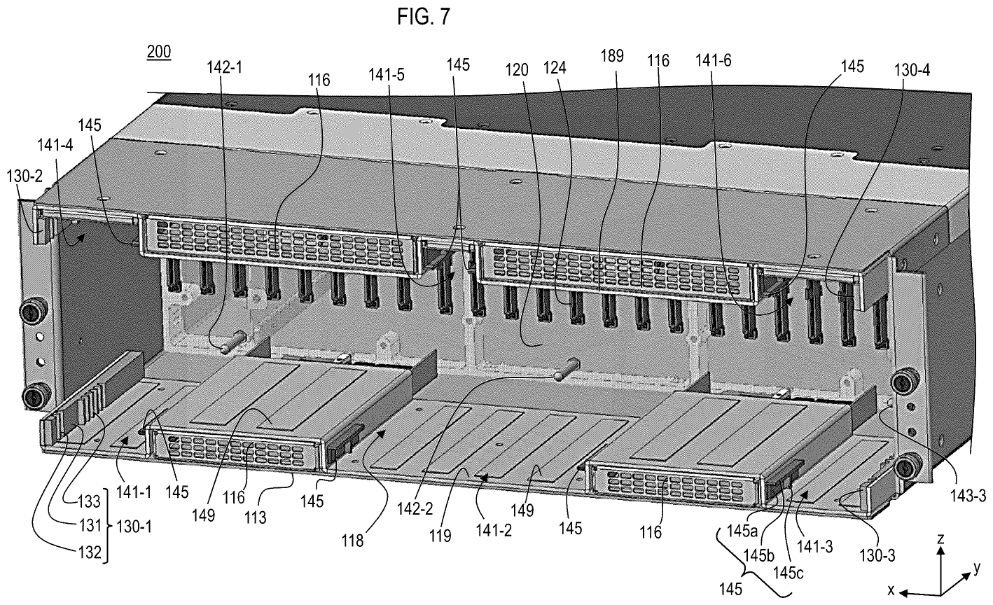

This chassis 111 may also include a drive cage receptacle 118 defined in the front panel thereof between the top wall 112, bottom wall 113, left side wall 114, and right side wall 115. In addition, the chassis 111 may comprise a bottom insert 119 which is mounted on the bottom wall 113 and forms a bottom of the receptacle 118, as best seen in FIG. 7. The chassis 111 also comprises a top insert 189, which is similar to the bottom insert 119 except the top insert 189 is mounted to the top wall 112 and forms a top of the receptacle 118, as shown in FIG. 7. In some examples, the bottom and top inserts 119 and 189 comprise mesa- or ridge-like raised portions defining auxiliary cages 116 (see FIGS. 7 and 2). These auxiliary cages 116 may house expansion cards, hardware accelerators, media drives, or any other desired electronic modules or components.

The inserts 119 and 189 may also comprise landing pads 149, which comprise additional mesa-like protrusions, smaller than those which form the auxiliary cages 116. These landing pads 149 may be formed both in the troughs 141 and in the raised portions of the inserts 119 and 189, as shown in FIGS. 4 and 7. The landing pads 149 are configured to slidingly engage with the drive cage 150 as the drive cage is inserted into or removed from the receptacle. The landing pads 149 may reduce the amount of frictional resistance to insertion/removal of the drive cage 150 that occurs, as the landing pads 149 may hold the bottom surface of the drive cage 150 apart from a portion of the surface of the inserts 119 and 189, thus reducing the surface area of the contact patch between the inserts 119/189 and the drive cage 150. Friction is generally proportional to the contact surface area, and thus the reduction in such area by use of the landing pads 149 can reduce friction. In some examples, the landing pads 149 may also have a low friction coating or sticker (e.g., Teflon), or be made from a low-friction material (e.g., nylon, brass, etc.).

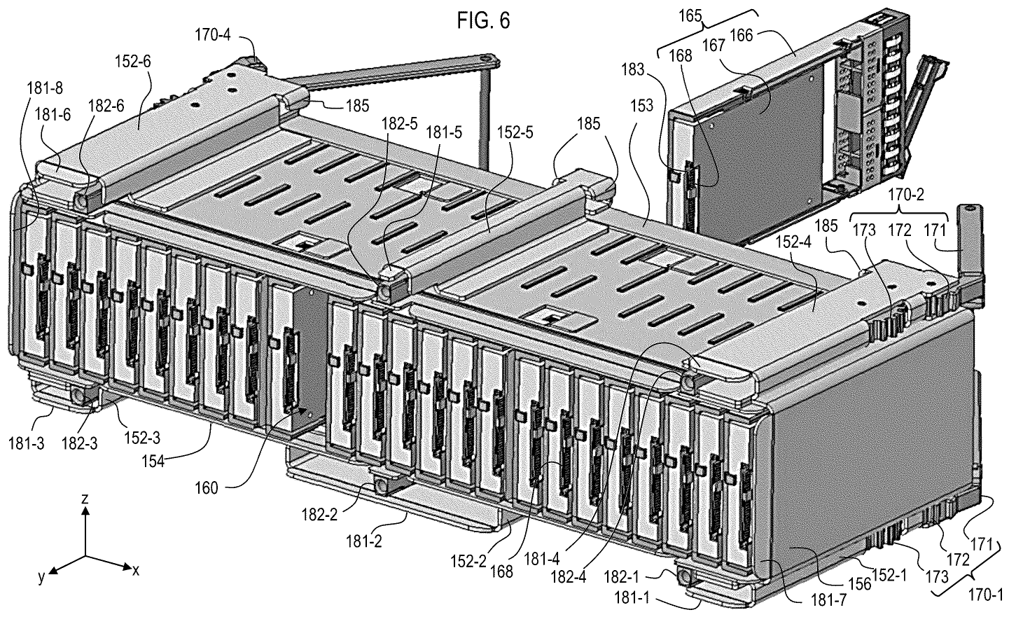

As shown in FIG. 7, a front of the receptacle 118 is open to allow for insertion of the drive cage 150, and a back portion thereof is also open to allow the interior of the receptacle 118 to communicate with a backplane 120 positioned at the rear of the receptacle 118. In other words, the backplane 120 is covers the back opening of the receptacle 118. As shown in FIG. 7, the backplane 120 has blind-mate electrical connectors 124 mounted thereon and positioned so as to engage with complementary connectors 168 (see FIG. 6) of the media drives 165 when the drive cage 150 is inserted into the drive cage receptacle 118. For example, the connectors 168 may comprise PCB-edge connector style connectors (also called gold-finger connectors or PCB-gold finger connectors), and the connectors 124 may comprise sockets (receptacles) configured to receive the connectors 168. The number and arrangement of blind-mate connectors 124 corresponds to the number and arrangement of drive bays 160 (discussed below) in the drive cage 150. The connectors 124 of the backplane 120 are electrically connected to information processing circuitry (not illustrated) of the device 110, such as a CPU, and thus the media drives 165 are connected with the information processing circuitry via the connectors 124 when the drive cage 150 is installed.

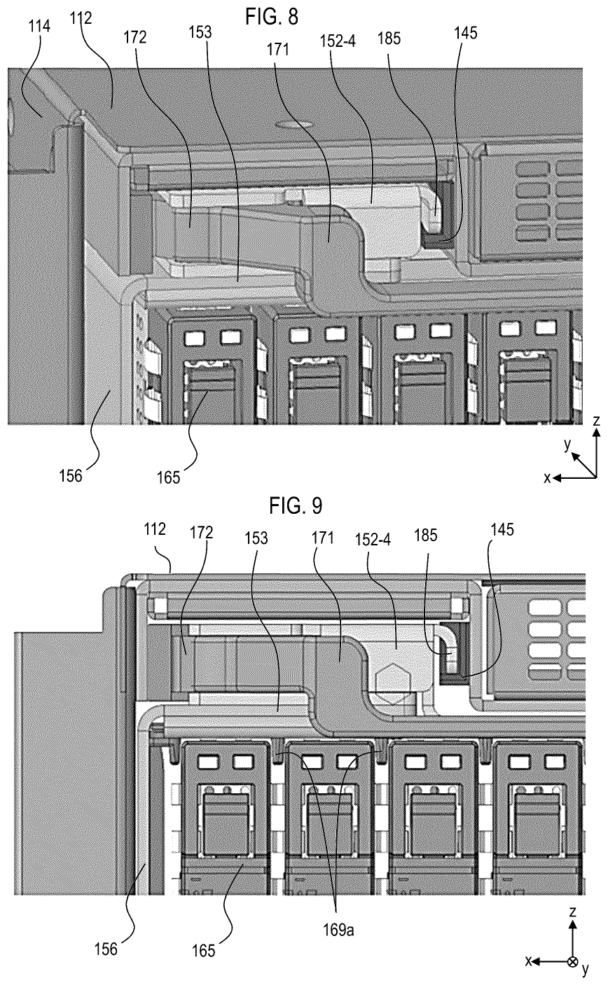

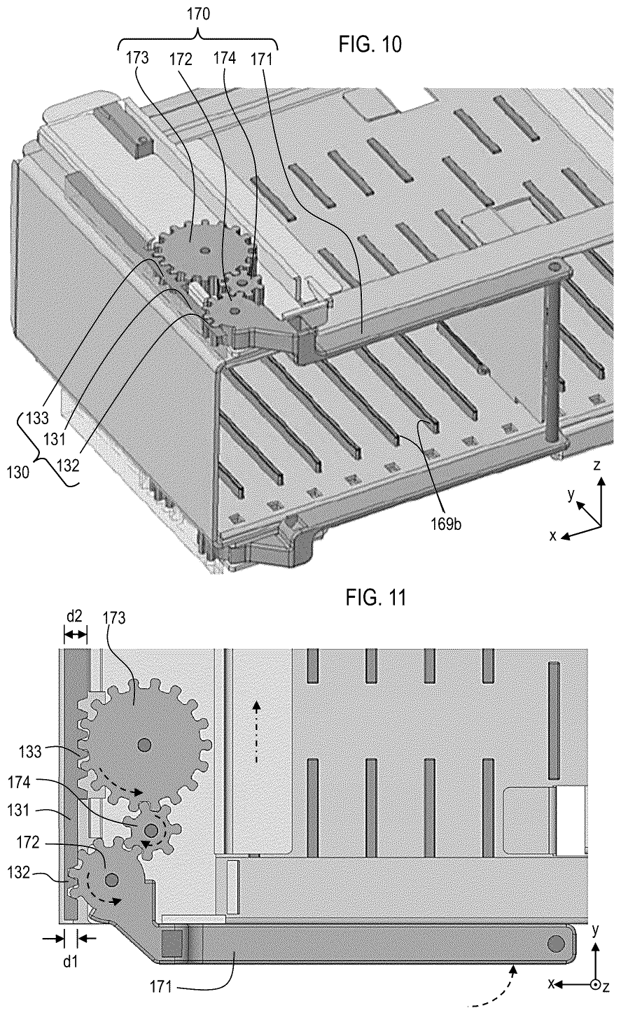

As shown in FIGS. 5 and 6, the drive cage 150 comprises a plurality of walls forming a structural frame that surrounds and defines multiple internal drive bays 160. Each of the drive bays 160 is configured to removably receive, hold, and support a media drive 165. The drive cage 150 frame comprises a top wall 153, a bottom wall 154, a left side wall 156, and a right side wall 155. As shown in FIG. 5, front portion of the drive cage 150 is substantially open to allow for media drives 165 to be inserted into and removed from the drive cage 150. In addition, as shown in FIG. 6, a rear portion of the drive cage 150 is also at least partially open so as to expose at least the electrical connectors 168 at the rear of the media drives 165. The bays 160 are configured to hold the media drives 165 in predetermined positions such that their electrical connectors will be properly aligned with, and thus can engage with, the electrical connectors 124 of the backplane 120 when the drive cage 150 is installed in the receptacle 118. Each bay may comprise one or more attachment and/or guide features that hold the drives 165 in the correct position, such as the guide features 169a shown in FIG. 9 or the guide features 169b shown in FIG. 10, which define boundaries between adjacent bays 160 and abut lateral sides of the media drives 165 to hold them in the correct lateral position within the bays 160. These illustrated guide features 169a and 169b are merely one example, and any type of guide and attachment features may be used, such as any of those used in bays of existing fixed drive cages. Additional guide or attachment features (not illustrated) may be present to constrain the forward-rearward (y-axis) position of the drives 165 and/or to releasably secure the media drives 165 in the bays 160, as would be familiar to those of ordinary skill in the art.

As shown in FIGS. 5 and 6, the drive cage 150 also comprises ridge-like protruding portions 152 on the top and bottom sides thereof. Specifically, the protruding portions 152-4, 152-5, and 152-6 are disposed on a top side of the drive cage 150 and protrude upward (in the +z direction) from the top wall 153, while protruding portions 152-1, 152-2, and 152-3 are disposed on a bottom side of the drive cage 150 and protrude downward (in the −z direction) from the bottom wall 154. The protruding portions 152-4, 152-5, and 152-6, together with the top wall 153, define a top surface of the drive cage 150. The protruding portions 152-1, 152-2, and 152-3, together with the bottom wall 154, define a bottom surface of the drive cage 150.

The protruding portions 152 are configured to face opposing surfaces of the receptacle 118 when the drive cage 150 is in an installed position, and each protruding portion 152 is received into a corresponding trough (groove) 141 defined in the receptacle 118. As shown in FIG. 7, the troughs 141 are formed in the spaces between a side wall of the chassis 111 and an adjacent auxiliary cage 116 or between two auxiliary cages 116. Specifically, the portion 152-1 is received in the trough 141-1, the portion 152-2 is received in the trough 141-2, and so on up to the portion 152-6 which is received in the trough 141-6.

The protruding portions 152 are also configured to contact and slide along those opposing surfaces of the receptacle 118 as the drive cage 150 is inserted into the receptacle 118. The receptacle 118 is necessarily somewhat larger than the drive cage 150, or else insertion of the drive cage 150 would not be feasible. Thus, the protruding portions 152 might not all simultaneously engage with the opposing surfaces during insertion, but instead one or more portions 152 may engage while others do not, depending on the circumstances. For example, if the system 105 is oriented such that gravity pulls in the −z direction, then the portions 152-1, 152-2, and 152-3 are likely to engage with and slide along the bottom insert 119 during insertion, due to the pull of gravity, whereas if the system 105 is oriented in an opposite orientation, the portions 152-4, 152-5, and 152-6 would instead engage with and slide along the top insert 189 during insertion. The protruding portions 152 also comprise, house, or support, various other components which will be described in greater detail below, such as injector/ejectors 170, alignment features 181 and 182, and lockdown features 186.

As shown in FIG. 6, the hot-swappable drive cage 150 comprises a series of progressive alignment features including first stage alignment features 181, second stage alignment features 182, and third stage alignment features 183. Each of these stages of alignment features engages with complementary features of the device 110 in sequential stages of engagement, with each stage progressively bringing the drive cage 150 closer to an ideal aligned position relative to the device 110. That is, the first stage alignment features 181 engage the device 110 first, during the initial insertion of the drive cage 150, to provide gross positioning of the drive cage 150 and guide the cage into the receptacle 118; subsequently, when the drive cage 150 has been advanced a certain distance into the receptacle 118, the second stage alignment features 182 engage with the device 110 and guide the drive cage 150 to move even closer to the aligned position; and then subsequently, when the drive cage 150 has been advanced even farther into the receptacle 118, the third engagement features 183 provide fine positional adjustments to bring the drive cage 150 (or the drives 165 contained therein) into (or sufficiently close to) the desired installed position. The first stage alignment features 181 comprise sloped lead-in surfaces which are arranged at a rear portion of the drive cage 150 on top, bottom, left, and right sides of the drive cage 150. The second stage alignment features 182 comprise pin receptacles which are also arranged at the rear of the drive cage 150. The third stage alignment features 183 comprise lead-in surfaces of the connectors 168 of the drives 165. These will all be described in greater detail below.

Specifically, on a bottom side of the drive cage 150, the first stage alignment features 181 include alignment features 181-1, 181-2, and 181-3 (see FIG. 6), which are coupled to and protrude generally rearward (+y direction) from the protruded portions 152-1, 152-2, and 152-3, respectively. In addition to protruding generally rearward, the alignment features 181-1, 181-2, and 181-3 have an engagement surface (the bottom surface thereof) that is sloped (angled) in an upward (+z direction) direction. In other words, the engagement surfaces of the alignment features 181-1, 181-2, and 181-3 extend rearward and upward at an angle relative to the horizontal x-y plane. As the drive cage 150 is inserted into the receptacle 118, if the drive cage 150 is slightly lower (i.e., displaced in the −z direction) than an ideally aligned position with the receptacle 118, then the alignment features 181-1, 181-2, and 181-3 engage with and slide along the leading edge of the bottom surface of the receptacle 118 (i.e., with insert 119). Due to the surfaces of the alignment features 181-1, 181-2, and 181-3 being sloped upward, the sliding engagement between these surfaces and the chassis converts the rearward (+y direction) motion of the drive cage 150 into motion angled upward and rearward, thus guiding the drive cage 150 into the receptacle 118 and closer to the aligned position.

On a top side of the drive cage 150, the alignment features 181 include alignment features 181-4, 181-5, and 181-6 (see FIG. 6), which are coupled to and protrude generally rearward (+y direction) from the protruded portions 152-1, 152-2, and 152-3, respectively. In addition to protruding generally rearward, the alignment features 181-4, 181-5, and 181-6 have an engagement surface (the top surface thereof) that is sloped (angled) in an downward (−z direction) direction. In other words, the engagement surfaces of the alignment features 181-4, 181-5, and 181-6 extend rearward and downward at an angle relative to the horizontal x-y plane. As the drive cage 150 is inserted into the receptacle 118, if the drive cage 150 is slightly higher (i.e., displaced in the +z direction) than an ideally aligned position with the receptacle 118, then the alignment features 181-4, 181-5, and 181-6 engage with and slide against the leading edge of the top surface of the receptacle 118 (i.e., with insert 189), and this results in the drive cage 150 being moved at an angle downward and rearward, thus guiding the drive cage 150 into the receptacle 118 and closer to the aligned position.

On a left side of the drive cage 150, the alignment features 181 include alignment feature 181-7 (see FIG. 6), which is coupled to and extends generally rearward (+y direction) from left side wall 156. In addition to protruding generally rearward, the alignment feature 181-7 has an engagement surface (the outward surface thereof) that is sloped (angled) in an inward (−x direction) direction. In other words, the engagement surface of the alignment feature 181-7 extends rearward and inward at an angle relative to the vertical y-z plane. As the drive cage 150 is inserted into the receptacle 118, if the drive cage 150 is slightly to the left of (i.e., displaced in the +x direction) the ideally aligned position with the receptacle 118, then the alignment feature 181-7 engages with and slides against the leading edge of the left side of the receptacle 118 (i.e., with racks 130-1 and 130-2), and this results in the drive cage 150 being moved at an angle rightward and rearward, thus guiding the drive cage 150 into the receptacle 118 and closer to the aligned position.

On a right side of the drive cage 150, the alignment features 181 include alignment feature 181-8 (see FIG. 6), which is coupled to and extends generally rearward (+y direction) from right side wall 155. In addition to protruding generally rearward, the alignment feature 181-8 has an engagement surface (the outward surface thereof) that is sloped (angled) in an inward (+x direction) direction. In other words, the engagement surface of the alignment feature 181-8 extends rearward and inward at an angle relative to the vertical y-z plane. As the drive cage 150 is inserted into the receptacle 118, if the drive cage 150 is slightly to the right of (i.e., displaced in the −x direction) the ideally aligned position with the receptacle 118, then the alignment feature 181-8 engages with and slides against the leading edge of the right side of the receptacle 118 (i.e., with racks 130-3 and 130-4), and this results in the drive cage 150 being moved at an angle leftward and rearward, thus guiding the drive cage 150 into the receptacle 118 and closer to the aligned position.

The above-described first stage alignment features 181 allow for the drive cage 150 to be out of alignment with the receptacle 118 by a substantial amount and yet still be guided into the receptacle 118. This makes it easier for a user to insert the drive cage 150, particularly in an adverse environment, as the user does not have to attempt to painstakingly align the drive cage 150 with the receptacle 118. In some examples, the first stage alignment features 181 are configured to provide up to 5 mm of positional correction for the drive cage in any given direction. In other words, in some examples the first stage alignment features 181 are configured to allow the drive cage 150 to be out of alignment with the receptacle 118 by up to 5 mm in any of the up, down, left, and right directions (or superpositions thereof) and still be able to guide the drive cage 150 into the receptacle 118.

Turning to the second stage alignment features 182, as shown in FIG. 6, these alignment features 182 alignment features 181-1 to 181-6 which are coupled to and partially housed within the protruded portions 152-1 to 152-6, respectively. Each of these alignment features 182 comprises a pin receptacle configured to receive a corresponding pin 142 of the device 110. In particular, as shown in FIG. 7, pins 142 are coupled to the backplane 120 and protruding into the receptacle 118 in positioned that align with the alignment features 181-1 to 181-6. Pins 142-1 to 142-3, which are visible in FIG. 7, align to and engage with features 181-1 to 181-3, respectively, and three additional pins 142 (not visible) align to and engage with features 181-4 to 181-6, respectively.

As the drive cage 150 is inserted into the receptacle 118, the first stage alignment features 181 discussed above may provide an initial gross alignment of the drive cage 150 relative to the receptacle 118 which results in the pins 142 being generally aligned with the alignment features 182. However, even after this initial gross alignment of the drive cage 150, some leeway (play) is deliberately provided between the drive cage and the receptacle 118 to make the insertion easier, and consequently the pins 142 may not be perfectly aligned with the pin receptacles of the second stage alignment features 182. Thus, to ensure that the pins 142 can engage with the pin receptacles notwithstanding this slight misalignment, each alignment feature 181 may comprise chamfered lead-in surfaces at an inlet of the pin receptacle and/or each pin 142 may comprise rounded or sloped (e.g., chamfered or pointed) lead-in surfaces at the tips thereof to facilitate engagement in the event of misalignment. In other words, the first stage of alignment features 181 bring the drive cage 150 close enough to the aligned position to ensure that the rounded or sloped lead in surfaces of the pins 142 and/or second stage alignment features 182 can engage one another, resulting in these surfaces sliding relative to one another and thus moving the drive cage 150 even closer to the desired installation position. In some examples, the second stage alignment features may provide up to about 2.5 mm of further positional alignment, on top of the gross alignment already provided by the first stage.

In addition to providing progressively tighter positional alignment, the pins 142 and alignment features (pin receptacles) 182 also serve as lockdown features to lockdown a rear side of the cage 150 to chassis 111. This provides extra rigidity and structural support to resist the relative motion of the drive cage 150 to the chassis 111. A front side of the cage 150 is also locked down to the chassis 111 by lockdown features 185 described in greater detail below.

Turning to the third stage alignment features 183, as shown in FIG. 6, these alignment features 183 comprise the lead-in surfaces of the electrical connectors 168 of the drives 165. These lead-in surfaces engage with lead-in surface of the connectors 124 to provide a final adjustment in position to the drives 165. That is, the second stage of alignment features 182 brings the drive cage 150 into sufficiently close alignment with the desired installation position that each electrical connectors 168 is able to engage with the corresponding electrical connector 124, but there may still be some very slight misalignment between these connectors, and this last small amount of misalignment may be alleviated by the third stage alignment features 183. For example, the lead-in surfaces of the connectors 168 and the connectors 124 may be chamfered or rounded such that, in the event of slight misalignment, these surfaces engage and slide along one another, thus moving the connectors 168 into full engagement with the connectors 124. In some examples, the third stage alignment features may provide up to about 0.8 mm of further positional alignment, on top of the alignment already provided by the first and second stages.

As shown in FIG. 2-7, the drive cage 150 also comprises four injector/ejector mechanisms 170 (also referred to as injector/ejectors 170), to aid the user in insertion of the drive cage 150 into or removal of the drive cage 150 from the drive cage receptacle 118. These injector/ejectors 170 include injector/ejector 170-1 positioned at a left bottom front corner region of the drive cage 150, injector/ejector 170-2 positioned at a left top front corner region of the drive cage 150, injector/ejector 170-3 positioned at a right bottom front corner region of the drive cage 150, and injector/ejector 170-4 positioned at a right top front corner region of the drive cage 150. Each injector/ejector 170 is configured to engage with a complementary injector/ejector engagement element 130 which is anchored to the chassis 111. In this example, the complementary injector/ejector engagement element 130 comprises a rack (linear gear), and thus may also be referred to as rack 130. As shown in FIGS. 3, 4, and 7, the racks 130-1 to 130-4 are disposed in the receptacle 118 at left bottom front, left top front, right bottom front, and right top front corners, respectively, of the receptacle 118. The racks 130-1 to 130-4 are arranged to engage with the corresponding injector/ejectors 170-1 to 170-4, respective, as the drive cage 150 is inserted into the receptacle 118.

As shown in FIGS. 3-5 and 8-13, each injector/ejector 170 comprises a lever 171 which is manually actuatable by the user. As shown in FIG. 5, the levers 171 of the two injector/ejectors 170-1 and 170-2 located on a left side of the drive cage 150 are coupled together via a first handle 175 that extends vertically therebetween. Similarly, the two injector/ejectors 170-3 and 170-4 located on a right side of the drive cage 150 are coupled together via a second handle 175 that extends vertically therebetween. Thus, a user can actuate all four injector/ejectors 170 simultaneously by grasping the two handles 175 (e.g., one in each hand) and pushing them simultaneously to pivot toward the drive cage 150 (a first actuation direction, used for injection), or pulling them simultaneously to pivot away from the drive cage 150 (a second actuation direction, used for ejection). In some examples, the handles 175 may also serve as carrying handles which allow for the user to carry the drive cage 150 when removed from the information processing device 110.

The injector/ejectors 170 are configured to convert the actuation forces applied to the levers 171 (via the handles 175) into injection forces and ejection forces, depending on the direction of actuation. To facilitate this force conversion, as shown in FIGS. 5 and 10-13, each injector/ejector 170 further comprises a gear assembly comprising at least a first pinion gear 172 coupled to the lever 171 such that actuation of the lever 171 is converted into rotation of the first pinion gear 172. As shown in FIGS. 5 and 10-13, the gear assembly further comprises a second pinion gear 173. The first pinion gear 172 and the second pinion gear 173 are linked so as to rotate together in a same direction. The pinion gears 172 and 173 are configured to engage with gear teeth of the racks 130, and this engagement converts rotation of the pinion gears 172 and 173 (as driven by actuation of the levers 171) into translation of drive cage 150 relative to the chassis 111.

For example, in one implementation illustrated in FIGS. 10-11, the gear assembly further comprises an intermediate gear 174, which links together the first and second pinion gears 172 and 173 (gear teeth of the intermediate gear 174 are enmeshed with gear teeth of both the first and second pinion gears 172 and 173). Thus, actuation of the lever 171 drives rotation of the first pinion gear 172, which drives rotation of the intermediate gear 174, which drives rotation of the second pinion gear 173. For example, if the levers 171 are in the position illustrated in FIG. 5 and then first actuation forces are applied thereto to move the levers 171 toward the drives 165, this results in the first pinion gear 172, intermediate gear 174, and second pinion gear 173 all rotating in the directions indicated by the dashed arrows in FIG. 11, and the interaction between the pinion gears 172 and 173 and the rack 131 converts this rotation into translational motion of the drive cage 150 relative to the chassis 111 farther into the receptacle 118 as indicated by the dot-dashed arrow in FIG. 11 (e.g., along the +y direction). Thus, the levers 171, gears 172, 173, and 174, and racks 130 convert the first actuation forces into injection forces. Eventually, the state illustrated in FIG. 11 is reached, resulting in the drive cage 150 being fully installed in the receptacle 118. Conversely, if the levers 171 are in the position illustrated in FIG. 11 and then second actuation forces are applied thereto to move the levers 171 away from the drives 165, this results in the first pinion gear 172, intermediate gear 174, and second pinion gear 173 all rotating in the directions opposite those indicated by the dashed arrows in FIG. 11, resulting in translational motion of the drive cage 150 in a direction out of the receptacle 118 (e.g., along the −y direction). Thus, the levers 171, gears 172, 173, and 174, and racks 130 convert the second actuation forces into ejection forces. Eventually, the state of the levers 171 illustrated in FIG. 5 is reached, resulting in the drives 165 being fully disconnected from the connectors 124 (although the drive cage 150 may still be partially inserted in the receptacle 118 at this point).

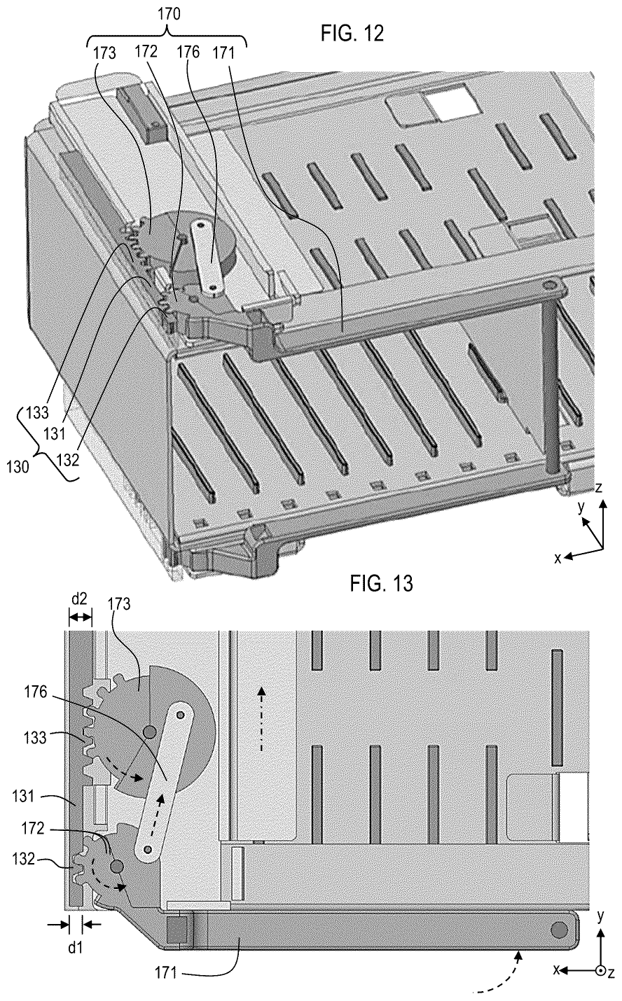

As another example, in one implementation illustrated in FIGS. 12-13, the first and second pinion gears 172 and 173 are linked together by a bar 176. The bar 176 is coupled to the gears 172 and 173 away from their centers. Thus, actuation of the lever 171 drives rotation of the first pinion gear 172, which drives translation of the bar 176, which drives rotation of the second pinion gear 173. For example, if the levers 171 are positioned as shown in FIG. 5 and the lever 171 is actuated towards drives 165, then the first pinion gear 172, bar 176, and second pinion gear 173 would move as indicated by the dashed arrows in FIG. 13, resulting in injection of the drive cage 150. Conversely, if the levers 171 are positioned as illustrated in FIG. 5 and then the lever 171 were moved in an opposite direction (away from the drives 165), the motion of the first pinion gear 172, bar 176, and second pinion gear 173 would be the opposite that indicated by the dashed arrows in FIG. 13, resulting in ejection of the drive cage 150.

As shown in FIGS. 10-13, each of the racks 130 may comprise multiple tiers 132, 133 which are arranged in a line (in a forward-rearward direction). A first tier 132 of the rack may be closest to the front of the receptacle 118 and may protrude into the receptacle a first distance d1 (see FIG. 11), and a second tier 133 of the rack 130 may be positioned rearward of the first tier 132 and may protrude a second distance d2 (see FIG. 11), which is greater than the first distance d1. In some examples, the first tier 132 is coupled to the second tier 133 by an intermediate portion 131, which may have a similar thickness as the first tier 132 but may lack gear teeth. In other examples, the first tier 132 and the second tier 133 may be separate pieces. The first pinion gear 172 engages with the first tier 132 of the rack 130, while the second pinion gear 173 engages with the second tier 133 of the rack 130, as shown in FIGS. 10-13. The second pinion 173 is offset relative to the first pinion gear 172 along the y-axis such that the second pinion 173 can pass by the first tier 132 of the rack 130 as the drive cage 150 is inserted into the receptacle 118 without the second pinion gear 173 engaging with the first tier 132 of the rack 130.

The engagement of the pinion gears 172 and 173 with the rack 130 converts rotation of the gears 172 and 173 translation of the drive cage 150 relative to the chassis 111. For example, if the gears 172 and 173 rotate in the directions illustrated by the dashed arrows in FIG. 11 or 13, the interaction of the gears 172 and 173 with the rack 130 causes the drive cage 150 to move out of the receptacle 118, as indicated by the dot-dashed arrows in FIG. 11 or 13. If the gears 172 and 173 rotate in the opposite direction, the drive cage 150 moves farther into the receptacle 118.

Accordingly, when a user actuates the handles 175 by pivoting them, the force applied by the user to the handles 175 is magnified by the mechanical advantage of the injector/ejectors 170 and is converted into a force which urges relative translation between the drive cage 150 and the chassis 111. When the drive cage 150 is partially installed in the receptacle 118 (e.g., the injector/ejector s170 are engaged with the racks 130, but the drives 165 are not yet engaged with the connectors 124), if the handles 175 are pushed to pivot towards the drives 165, a force is generated which pushes the drive cage 150 farther into the receptacle 118 until the drive cage 150 reaches a fully installed position in which the drives 165 are fully connected to the connector 124. In contrast, when the drive cage 150 is fully installed in the receptacle 118, if the handles 175 are pulled to pivot away from the drives 165, a force is generated which pushes the drive cage 150 out of the receptacle 118, disconnecting all of the drives 165 from the connectors 124. In this manner, the injector/ejectors 170 can help the user overcome the frictional resistance to the simultaneous engagement or disengagement of the drives 165 to/from the electrical connectors 124 of the backplane 120. In some examples, the mechanical advantage provided by each injector/ejector 170 is about 12:1, in other examples about 10:1, and in other examples about 7.5:1.

One difficulty that arises with providing a removable drive cage (in addition to the difficulties of achieving alignment of a removable drive cage with the backplane connectors and of overcoming the insertion/removal resistance forces) is ensuring that the drive cage 150 does not move about while installed in the receptacle 118. For example, shocks, vibration, or accelerations may all tend to urge motion of the drive cage 150 within the receptacle 118. The injection/ejection mechanisms 170, together with the frictional resistance of the electrical connections between connectors 124 and 168, may prevent forward/reward motion of the drive cage 150. However, motion of the drive cage 150 in other directions is not prevented. Of course, the walls of the receptacle 118 do constrain the motion of the drive cage 150 somewhat, but as already noted above some play is deliberately built in between the cage 150 and receptacle 118 to make the insertion and removal easier, and it is within the bounds of this play that the drive cage 150 might move up, down, left, or right. Such motion can cause damage to the connectors 124 of the backplane 120 and/or to the connectors 128 of the drives 165. In addition, such motion if harsh or repeated (shocks or vibrations) may also damage internal components of the drives 165 held in the cage 150.

Thus, to avoid such motion of the drive cage 150 when installed, the drive cage 150 comprise lockdown features which are configured to lockdown the drive cage 150 relative to the chassis 611 to prevent excessive motion (in some cases, prevent any motion) of the drive cage 150 relative to the chassis 611. As already mentioned above, the lockdown features for locking down a rear side of the drive cage 150 include the pins 142. In addition, lockdown features 185 are provided for locking down a front side of the drive cage 150. The lockdown features 185 are configured to engage with rails 145 disposed in the receptacle 118 and anchored to the chassis 111. The lockdown features 185 and rails 145, when engaged, lock in a position of the drive cage 150 relative to the receptacle 118 and substantially prevent (or, at the very least, inhibit) motion of the drive cage 150 relative to the receptacle 118.

As shown in FIGS. 3 and 4, the lockdown features 185 are disposed along both top-front and bottom-front edges of the drive cage 150. Each lockdown feature 185 is coupled to (e.g., formed from) one of the protruded portions 152. Specifically, as shown in FIGS. 3 and 4, the protruded portions 152-1, 152-3, 152-4, and 152-6 each comprises one lockdown feature 185, while the protruded portions 152-2 and 152-5 each comprise two lockdown features 185. The rails 145 are disposed in the troughs 141 and attached to the lateral sides of the auxiliary cages 116, as shown in FIGS. 3, 4, and 7.

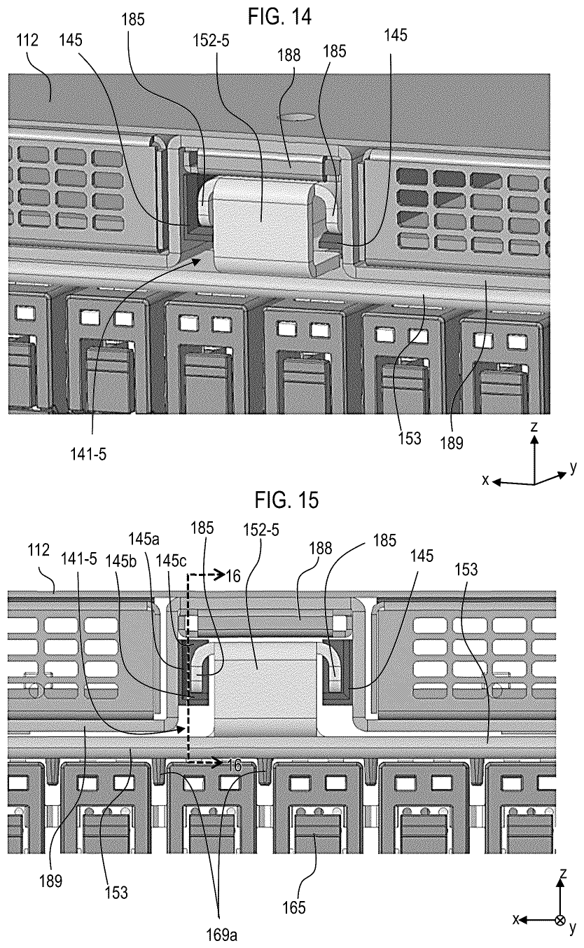

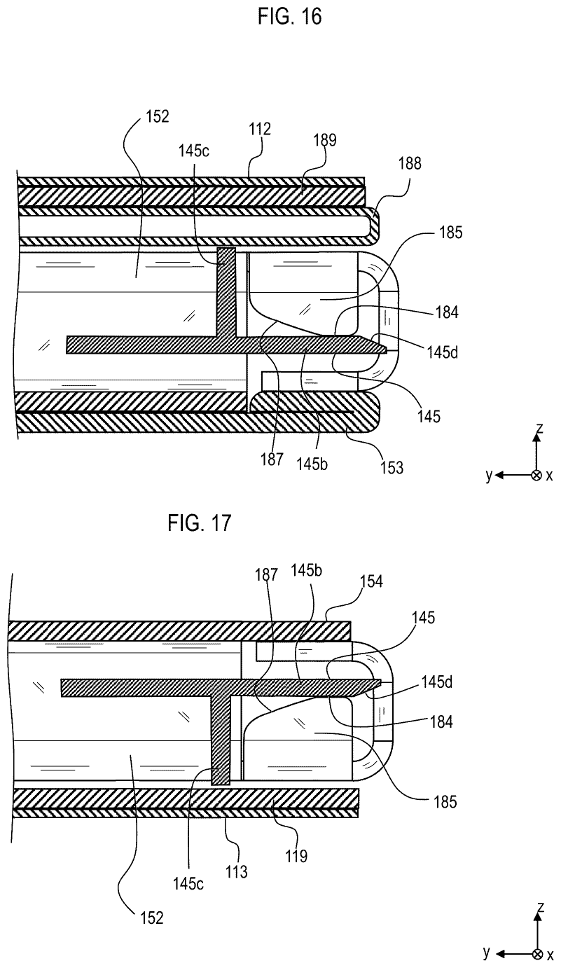

As shown in FIGS. 7 and 16, the rails 145 comprise a side vertical portion 145a which is attached to the auxiliary cage 116, a horizontal portion 145b extending perpendicularly from the vertical portion, and a vertical support 145c perpendicular to the other two portions. In some examples, the rails 145 comprise plastic over molded over a metal frame. As shown in FIG. 7, for the rails 145 positioned along a bottom of the receptacle 118, the horizontal portion 145b forms a top of the rail 145, whereas for the rails 145 positioned along the top of the receptacle 118 the horizontal portion 145b forms the bottom of the rails 145. As shown in FIGS. 14-17, in some examples the front edges 145d of the horizontal portions 145b may be sloped/chamfered to aid in guiding the lockdown features 185 into the engaged position in the event of an initial misalignment.

As shown in FIGS. 5, 6, 16, and 17 each lockdown feature 185 comprises a sloped ramp 187 and a landing portion 184. The ramps 187 are configured to contact and slide along a front edge 145d of the rail 145, which pushes the lockdown feature 185 up or down (depending on the orientation of the lockdown feature 185 and the rail 145) until the landing portion 184 is resting on the horizontal portion 145b of the rail 145, as shown in FIGS. 14-17. More specifically, the lockdown features 185 which are positioned on the top edge of the drive cage 150 are pushed upward (+z direction) onto the horizontal portion 145b of the rail 145, as shown in FIG. 17. In contrast, the lockdown features 185 which are positioned on the bottom edge of the drive cage 150 are pushed downward (−z direction) onto a bottom side of the horizontal portion 145b, as shown in FIG. 17. The lockdown features 185 and the rails 145 are configured such that, when the lockdown features 185 and the rails 145 are all engaged, the bottom-side lockdown features 185 are all held firmly against the horizontal portions 145b of the bottom-side rails 145 while the top-side lockdown features 185 are all held firmly against the horizontal portions 145b of the top-side rails 145, with no gaps. Thus, because the lockdown features 185 are mounted to opposite sides of the rails 145 with no gaps therebetween, the drive cage 150, which is coupled to the lockdown features 185, cannot move in the vertical (z-axis) directions. For example, if the drive cage 150 attempts to move downward, the top-side lockdown features 185 engaged with the top-side rails 145 (FIG. 16) prevent this motion; conversely, if the drive cage 150 attempts to move upward, the bottom-side lockdown features 185 engaged with the bottom-side rails 145 (FIG. 17) prevent this motion. Thus, the drive cage 150 is locked down and cannot move vertically.

In some examples, the positioning may be such that the horizontal portion 145b of the rails 145 actually interferes with the lockdown features 185 as the drive cage 150 is inserted, even if the drive cage is perfectly aligned, and therefore in order for the lockdown features 185 to achieve the positions shown in FIGS. 16 and 17 some slight elastic deformation (e.g., bending) of the rails 145 and/or lockdown features 185 may occur. This elastic deformation generates a spring force which further helps to lock down the drive cage 150.

In addition to locking the drive cage 150 in the up/down direction, the lockdown features 185 and the rails 145 may prevent movement of the drive cage 150 along +/−x directions. For example, as shown in FIGS. 3, 14, and 15, the vertical portion 145a of each rail 145 may laterally abut the lockdown features 185. Moreover, some of the rails 145 are positioned on a left side of a lockdown feature 185 while other rails are positioned on a right side of a lockdown features 185, such that the drive cage 150 is constrained in both left and right directions by the rails 145. As shown in FIGS. 14 and 15, the leading edges of the vertical portions 145a may be sloped/chamfered to aid in guiding the lockdown features 185 into the engaged position in the event of an initial misalignment.

In the description above, various types of electronic circuitry are described. As used herein, “electronic” is intended to be understood broadly to include all types of circuitry utilizing electricity, including digital and analog circuitry, direct current (DC) and alternating current (AC) circuitry, and circuitry for converting electricity into another form of energy and circuitry for using electricity to perform other functions. In other words, as used herein there is no distinction between “electronic” circuitry and “electrical” circuitry.

It is to be understood that both the general description and the detailed description provide examples that are explanatory in nature and are intended to provide an understanding of the present disclosure without limiting the scope of the present disclosure. Various mechanical, compositional, structural, electronic, and operational changes may be made without departing from the scope of this description and the claims. In some instances, well-known circuits, structures, and techniques have not been shown or described in detail in order not to obscure the examples. Like numbers in two or more figures represent the same or similar elements.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as connected may be electronically or mechanically directly connected, or they may be indirectly connected via one or more intermediate components, unless specifically noted otherwise. Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Elements and their associated aspects that are described in detail with reference to one example may, whenever practical, be included in other examples in which they are not specifically shown or described. For example, if an element is described in detail with reference to one example and is not described with reference to a second example, the element may nevertheless be claimed as included in the second example.

Unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

Further modifications and alternative examples will be apparent to those of ordinary skill in the art in view of the disclosure herein. For example, the devices and methods may include additional components or steps that were omitted from the diagrams and description for clarity of operation. Accordingly, this description is to be construed as illustrative only and is for the purpose of teaching those skilled in the art the general manner of carrying out the present teachings. It is to be understood that the various examples shown and described herein are to be taken as exemplary. Elements and materials, and arrangements of those elements and materials, may be substituted for those illustrated and described herein, parts and processes may be reversed, and certain features of the present teachings may be utilized independently, all as would be apparent to one skilled in the art after having the benefit of the description herein. Changes may be made in the elements described herein without departing from the scope of the present teachings and following claims.

It is to be understood that the particular examples set forth herein are non-limiting, and modifications to structure, dimensions, materials, and methodologies may be made without departing from the scope of the present teachings.

Other examples in accordance with the present disclosure will be apparent to those skilled in the art from consideration of the specification and practice of the invention disclosed herein. It is intended that the specification and examples be considered as exemplary only, with the following claims being entitled to their fullest breadth, including equivalents, under the applicable law.

What is claimed is:

1. An information processing system comprising:
an information processing device comprising:
a chassis defining a drive cage receptacle; and
information processing circuitry housed in the chassis;
a hot-swappable drive cage comprising a plurality of bays with a plurality of media drives mounted in the bays, wherein the drive cage is removably installable in the drive cage receptacle such that the drive cage and the media drives mounted in the bays are insertable in and removable from the drive cage receptacle together as a unit, wherein in an installed state of the hot-swappable drive cage in the drive cage receptacle, the media drives are electrically connected to the information processing circuitry.

2. The information processing system of claim 1,
wherein the drive cage comprises one or more injector/ejector mechanisms configured to, in a state of the drive cage in the drive cage receptacle, engage with a corresponding engagement element coupled to the chassis and convert actuation forces supplied to the injector/ejector mechanisms into insertion forces and ejection forces that force the drive cage to translate relative to the chassis into an installed position or out from the installed position.

3. The information processing system of claim 2,
wherein each of the one or more injector/ejector mechanisms comprises a lever and a gear assembly comprising one or more pinion gears, wherein each of the engagement elements comprise a rack, wherein actuation of the lever drives rotation of the pinion gears, and wherein rotation of the pinion gears drives translation of the drive cage relative to the chassis.

4. The information processing system of claim 3,
wherein the one or more injector/ejector mechanisms comprise four injector/ejector mechanisms arranged at four corners of the drive cage, and wherein the respective levers of two of the injector/ejector mechanisms are coupled together by a handle and the respective levers of two others of the injector/ejectors mechanism are coupled together by a handle.

5. The information processing system of claim 3,
wherein, for each of the injector/ejector mechanisms, the one or more pinion gears comprise a first pinion gear coupled to the lever and a second pinion gear linked to the first pinion gear such that the first and second pinion gears rotate together, and the corresponding engagement element comprises a multi-tiered rack comprising a first tier to engage with the first pinion gear and a second tier to engage with the second pinion gear, wherein the second tier protrudes farther than the first tier.

6. The information processing system of claim 5,
wherein, for each of the injector/ejector mechanisms, the gear assembly comprises an intermediate gear linking the first pinion gear to the second pinion gear.

7. The information processing system of claim 5,
wherein, for each of the injector/ejector mechanisms, the gear assembly comprises a bar linking the first pinion gear to the second pinion gear.

8. The information processing system of claim 3,
wherein each of the injector/ejector mechanisms is configured to provide generate an injection force and an ejection force that is at least ten times greater than an actuation force applied to actuate the respective injector/ejector mechanism.

9. The information processing system of claim 1,
wherein the drive cage comprises one or more alignment features to engage with the chassis to guide the drive cage into an installed position.

10. The information processing system of claim 9,
wherein the one or more alignment features comprise multiple stages of alignment features configured to engage with the chassis sequentially such that each stage of alignment features progressively moves the drive cage closer to the installed position.

11. The information processing system of claim 10,
wherein the stages of alignment features include a first stage of alignment features comprising sloped surfaces at a rear of the drive cage configured to guide the drive cage into the drive cage receptacle, and a second stage of alignment features comprising pin receptacles configured to receive pins of the information processing device if the drive cage is inserted a predetermined distance in to the drive cage receptacle.

12. The information processing system of claim 1,
wherein the drive cage comprises lockdown features configured to engage with rails attached to the chassis in the receptacle if the drive cage is in the installed position to contain motion of the drive cage.

13. The information processing system of claim 12,
wherein the lockdown features comprise ramps and landing surfaces, wherein the rails comprise horizontal portions, wherein the ramps are configured to engage with and slide along the horizontal portions until the landing surfaces rest upon the horizontal portions,
wherein, when the landing surfaces rest upon the horizontal portions, engagement between the landing surfaces and the horizontal portions prevents motion for the drive cage in any vertical directions.

14. The information processing system of claim 13,
wherein the rails comprise vertical portions, when the landing surfaces rest upon the horizontal portions, the vertical portions abut lateral sides of the lockdown features and prevent lateral motions of the drive cage.

15. The information processing system of claim 1,
wherein the information processing device comprises a backplane positioned at a rear of the drive cage receptacle and comprising electrical connectors configured to engage with the media drives in the installed state of the drive cage to electrically connect the media drives to the information processing circuitry.

16. The information processing system of claim 15,
wherein, as the drive cage is moved to the installed state in the drive cage receptacle, all of the media drives mounted in the bays simultaneously engage with the electrical connectors of the backplane, and as the drive cage is moved out of the installed state in the drive cage receptacle, all of the media drives mounted in the bays simultaneously disengage from the electrical connectors of the backplane.

17. A hot-swappable drive cage, comprising:
outer walls coupled together to form a frame defining a plurality of internal bays configured to removably receive a plurality of media drives, respectively, wherein the drive cage together with the media drives mounted in the bays are removably insertable, together as a unit, into a drive cage receptacle of an information processing device; and
one or more injector/ejector mechanisms coupled to the frame and configured to, in a state of the drive cage in the drive cage receptacle, engage with one or more corresponding engagement elements coupled to a chassis of the information processing device, respectively, and convert actuation forces supplied to the injector/ejector mechanisms into insertion forces and ejection forces that force the drive cage to translate relative to the chassis into an installed position or out from the installed position, wherein in the installed position the media drives are electrically connected to the information processing circuitry.

18. The drive cage of claim 17,
wherein each of the one or more injector/ejector mechanisms comprises a lever and a gear assembly comprising one or more pinion gears, wherein each of the engagement elements comprise a rack, wherein actuation of the lever drives rotation of the pinion gears, and wherein rotation of the pinion gears drives translation of the drive cage relative to the chassis.

19. The drive cage of claim 18,
wherein the one or more injector/ejector mechanisms comprise four injector/ejector mechanisms arranged at four corners of the drive cage, and wherein the respective levers of two of the injector/ejector mechanisms are coupled together by a handle and the respective levers of two others of the injector/ejectors mechanism are coupled together by a handle.

20. A method, comprising:
inserting a hot-swappable drive cage into a drive cage receptacle of an information processing device while the drive cage is carrying a plurality of media drives in bays defined in the drive cage;
translating the drive cage farther into drive cage receptacle until one or more injector/ejector mechanisms of the drive cage engage with corresponding engagement elements of the information processing device;
supplying first actuation forces to the injector/ejector mechanisms to actuate the injector/ejector mechanisms in a first direction;
converting the first actuation forces, by the injector/ejector mechanisms, into insertion forces that force the drive cage into an installed position in the drive cage receptacle and cause simultaneous engagement of the media drives with electrical connectors of the information processing device;
supplying second actuation forces to the injector/ejector mechanisms to actuate the injector/ejector mechanisms in a second direction;
converting the second actuation forces, by the injector/ejector mechanisms, into ejection forces that force the drive cage out of the installed position in the drive cage receptacle and cause simultaneous disengagement of the media drives from the electrical connectors of the information processing device.
